(19) United States
(12) Patent Application Publication
(10) Pub. No.: US 2003/0061010 A1
(43) Pub. Date: Mar. 27, 2003

(54) Multi-function data acquistion system and method

(76) Inventor: Thomas W. Durston, Oceanside, CA (US)

Correspondence Address: Pillsbury Winthrop LLP, Intellectual Property Group, 50 Fremont Street, San Francisco, CA, 94105, US

(21) Appl. No.: 09/967,633

(22) Filed: Sep. 26, 2001

(51) Int. Cl. G01R 13/00; G06F 19/00; G01R 29/26; H03F 1/26; G06F 15/00; H04B 15/00

(52) U.S. Cl. 702/189

(57) ABSTRACT

A system and method of data acquisition for transmission line performance evaluation and fault detection applications may incorporate wideband topology from reception of signals to be analyzed through to a high speed analog to digital converter. In accordance with one aspect of the present invention, for example, wideband variable gain amplifier and attenuation circuitry may be employed in conjunction with high speed sampling circuitry to facilitate event detection in a transmission line or wire; this implementation additionally allows seamless integration of spectrum analysis functionality in a single data acquisition system.

### CROSS-REFERENCE TO RELATED APPLICATIONS

The present Application is related to U.S. Application Serial No. ______, filed ______, titled TIME DOMAIN REFLECTOMETER WITH DIGITALLY GENERATED VARIABLE WIDTH PULSE OUTPUT (Attorney Docket No. 083277-0272108), and U.S. Application Serial No. ______, filed ______, titled TIME DOMAIN REFLECTOMTER WITH WIDEBAND DUAL BALANCED DUPLEXER LINE COUPLING CIRCUIT (Attorney Docket No. 083277-0272109), the disclosures of which are incorporated herein by reference.

### FIELD OF THE INVENTION

Aspects of the present invention relate generally to analysis of transmission lines, and more particularly to a system and method of data acquisition for transmission line performance analysis and fault detection applications.

### DESCRIPTION OF THE RELATED ART

Time domain reflectometer (TDR) technology has been traditionally employed to detect faults, or “events,” which are generally characterized by impedance discontinuities or variations from nominal impedance, for example, in wire-lines such as telephone, twisted pair, unshielded twisted pair (UTP), and television (co-axial) cables, was well as other transmission lines known in the art. Separately, spectrum analyzer technology seeks to ascertain the spectral content of transmitted signals propagating through such transmission lines.

In a typical data acquisition system for use in fault detection applications, a TDR employs a pulse generator to transmit a signal pulse, or incident pulse, of electromagnetic energy through the line to be tested; a fault or impedance discontinuity existing in the line will generally reflect at least a portion of the incident pulse back to the TDR. Analysis of a detected event may be based upon numerous parameters such as, inter alia, the duration and frequency of the incident pulse, the magnitude of the reflected signal, the time delay between transmission of the incident pulse and subsequent reception of the reflected signal, and the like.

In accordance with existing systems and methods, conventional data acquisition technologies allow only a single data point to be sampled per incident pulse transmitted by the TDR; this limitation results in low signal acquisition rates, and consequently, sluggish TDR performance during normal use in certain operational modes. Additionally, restricting a TDR to acquiring a single data sample per transmitted incident pulse prevents implementation of an integrated spectrum analyzer function into a single data acquisition apparatus or unit.

Inadequate design and overall configuration of testing hardware represent important factors contributing to deficient performance and versatility of traditional transmission line test equipment. For example, a conventional TDR incorporates sampler circuitry at the input of the system; reflections of incident pulses received by the TDR are directed through the sampler to a low bandwidth amplifier and low bandwidth analog to digital (A/D) converter circuitry. While limited improvements may be achieved through use of more suitable amplification technology, as is generally known in the art, conventional variable gain and attenuation circuits are commonly constituted by complex arrays of analog selectors and resistors implemented around operational amplifier (Op-Amp) stages; introduction of such variable gain amplifier and attenuator components substantially increases both the complexity and the expense of data acquisition systems. Further, as noted briefly above, a solution based upon improved amplification and attenuation only addresses one aspect of the problem; narrow bandwidth low speed sampler circuitry and the configuration of existing hardware does not accommodate integration of TDR fault detection and spectrum analyzer functionality.

### BRIEF DESCRIPTION OF THE DRAWINGS

FIG. 1 is simplified block diagram illustrating one embodiment of a multifunction data acquisition system.

FIG. 2 is a simplified block diagram illustrating one embodiment of multifunctional data acquisition circuitry.

FIG. 3 is a simplified block diagram illustrating one embodiment of a data acquisition method.

### DETAILED DESCRIPTION

Embodiments of the present invention overcome various shortcomings of conventional technology, providing a system and method of wideband data acquisition for transmission line performance evaluation and fault detection applications. In accordance with one aspect of the present invention, for example, wideband variable gain amplifier and attenuation circuitry may be employed in conjunction with high speed sampling circuitry to facilitate event detection in a transmission line or wire; this implementation additionally allows seamless integration of spectrum analysis functionality in a single data acquisition system.

The foregoing and other aspects of various embodiments of the present invention will be apparent through examination of the following detailed description thereof in conjunction with the accompanying drawings.

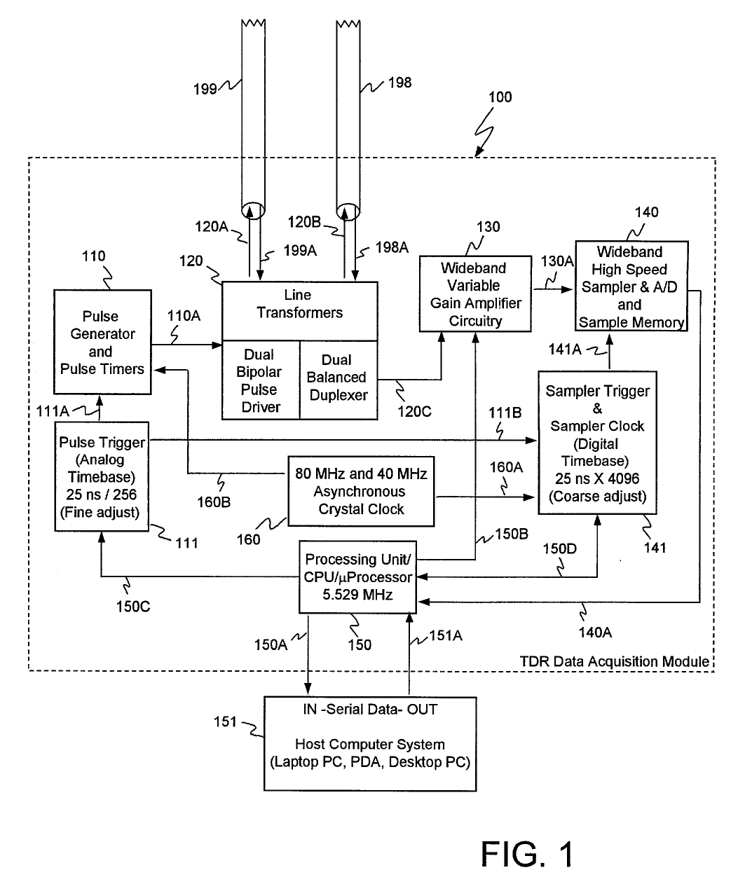

Turning now to the drawings, FIG. 1 is a simplified block diagram illustrating one embodiment of a multi-function data acquisition system. In the FIG. 1 embodiment, a data acquisition module 100 incorporates time domain reflectometer (TDR) functionality with spectrum analyzer capabilities as set forth in detail below. Module 100 generally comprises the following: a pulse generator 110; line transformers 120; high speed wideband variable gain amplifier and attenuation circuitry (amplifier component) 130; a wideband high speed sampler, A/D converter, and sample data storage medium or memory (sampler component) 140; and a processing unit 150. Additionally, module 100 may include a pulse trigger 111, a sampler trigger 141, and an asynchronous clock 160 coupled as illustrated in FIG. 1.

A user or technician at a host computer system 151 may selectively control operational characteristics or functionality of module 100 as described below. As indicated in FIG. 1, host computer 151 may be embodied in a desktop personal computer (PC) or workstation, a portable or laptop computer system, a personal digital assistant (PDA), or other electronic equipment or computerized systems having suitable hardware and software to support a two-way data communication coupling (represented by reference numerals 150A and 151A) to module 100.

In that regard, host computer 151 may be coupled to module 100 using various hardware interfaces and communication protocols known in the art; while this coupling is illustrated as a serial data link in FIG. 1, those of skill in the art will appreciate that bidirectional data communication between processing unit 150 and host computer 151 may be enabled by any hardware interface and data transmission protocol known in the art or developed and operative in accordance with known principles. In some embodiments, for example, module 100 may be coupled to a remote host computer 151 via a wire-line or wireless network connection. Examples of suitable hardware connections and protocols for coupling processing unit 150 and host computer 151 include, but are not limited to: Transmission Control Protocol/Internet Protocol (TCP/IP); Ethernet connections; Fiber Distributed Data Interface (FDDI); ARCNET; token bus or token ring networking technology; Universal Serial Bus (USB) connections; and Institute of Electrical and Electronics Engineers (IEEE) Standard 1394 (typically referred to as “FireWire”) connections.

During operation of module 100, pulse trigger 111 may control pulse generation, transmitting a pulse trigger signal 111A to pulse generator 110. As indicated in FIG. 1, pulse trigger 111 may be responsive to a control signal 150C transmitted from processing unit 150, and may fine tune a pulse delay by dividing a default delay time or clock cycle (25 nanoseconds (ns), for example) into a selected one of a predetermined number of increments (256 increments, for example). Accordingly, analog time base pulses may selectively delay pulse trigger signal 111A from a relatively long 25 ns to a relatively short 0.097 ns, i.e. 25 ns/256.

As is generally known in the art, pulse generator 110 may transmit a pulse 110A responsive to trigger signal 111A and a timing signal 160B from clock 160. Line transformers 120 may comprise wideband coupling circuitry capable of operating in the 10 kHz-500 MHz frequency range; in that regard, a dual bipolar pulse driver and a dual balanced duplexer may be provided to analyze two transmission lines (designated by reference numerals 199 and 198) simultaneously. In particular, a bipolar pulse driver may be operative to alter input pulse 110A in a manner appropriate for the specific test to be conducted on lines 199,198; such a suitable pulse driver may then create and transmit incident pulses 120A and 120B through transmission lines 199 and 198, respectively. Incident pulses 120A, 120B may be of any selected frequency and duration specified by processing unit 150 under control of host computer 151.

Transmission lines 199 and 198 may be telephone lines, twisted pair lines, unshielded twisted pair (UTP) lines, co-axial cables such as used to transmit cable television signals, fiber-optic cables, and the like. Those of skill in the art will appreciate that the present multi-function data acquisition system and method may provide integrated TDR and spectrum analysis functionality for analysis of any number of data transmission line types or variations; the present disclosure is not intended to be limited by the constitution of transmission lines 199,198 nor the nature of the signals carried therein.

Events or impedance discontinuities existing in transmission lines 199 and 198 may create reflection pulses 199A and 198A, respectively, which may be received by the dual balanced duplexer component of the line transformers 120. In operation, the duplexer may provide amplification of received reflection pulses 199A, 198A; such amplification at the receiver side of line transformers 120 may be a factor of 2 or more (2X) for typical TDR applications and line performance or spectrum analyses. In some embodiments, the duplexer may additionally be configured to attenuate or to cancel incident pulses 120A, 120B or their effects on the receiver side of line transformers 120, minimizing or eliminating the “dead zone” characteristic of conventional TDR equipment.

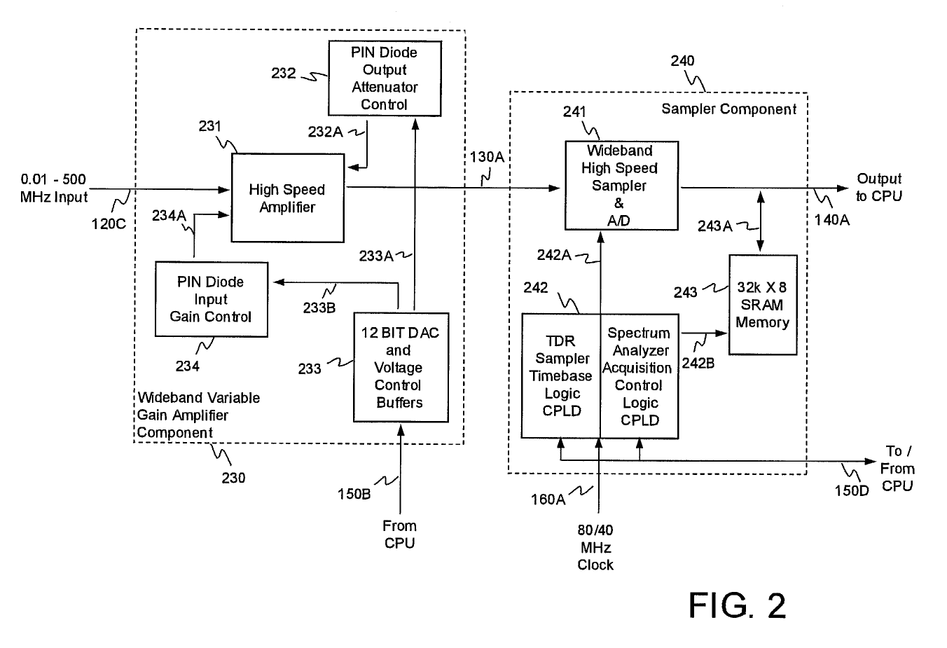

As indicated in FIG. 1, the duplexer may be configured to transmit a signal 120C representative of reflection pulses 199A, 198A to high speed wideband variable gain amplifier component 130; as set forth in detail below with reference to FIG. 2, amplifier component 130 may provide both amplification and attenuation functionality responsive to a control signal 150B transmitted from processing unit 150. Output 130A from amplifier component 130 may be directed to sampler component 140.

Sampler component 140 may generally be constituted by a high speed sampler, a high speed A/D converter, and memory for storing sample data. The sampler may sample the input (130A) at discrete time intervals or on a continuous, or streaming, basis; in that regard, sampler operation may be controlled by a sampler trigger signal 141A transmitted from sampler trigger 141 which, in turn, may be operative in accordance with a control signal 150D transmitted from processing unit 150. In this embodiment, for instance, control signal 150D may determine the operational mode in which sampler component 140 functions (i.e. discrete samples or streaming conversion at a particular frequency), while trigger signal 141A also provides information sufficient to determine the sample rate or frequency employed.

It will be appreciated that sampler trigger 141 may be operative in accordance with timing signals 160A received from clock 160 as well as control signal 150D. As is generally known in the art, asynchronous clock 160 may be configured to provide signals at two different clock rates, e.g 80 MHz and 40 MHz, as shown in FIG. 1. In contrast to pulse trigger 111, sampler trigger 141 may employ a digital time base generating signals in particular increments (25 ns in the FIG. 1 embodiment, for example) responsive to timing signal 160A.

In some embodiments, the sampler may provide sample data to the A/D converter, which may subsequently transmit digital data signals (represented by signal 140A) to processing unit 150 immediately; additionally or alternatively, output from the A/D converter may be stored as digital data samples temporarily in memory.

The memory component may be implemented in random access memory (RAM) chips, for example, or any other suitable data storage medium configured and operative to store or to buffer digital data including, but not limited to: fast static random access memory (SRAM) or transistor-based memory components; erasable programmable read only memory (EPROM); flash memory; various magnetic, optical, or magneto-optical disc media; and the like.

FIG. 2 is a simplified block diagram illustrating one embodiment of multifunctional data acquisition circuitry. In the FIG. 2 embodiment, wideband variable gain amplifier component 230 may generally correspond to amplifier component 130 described above with reference to FIG. 1, and may incorporate all of the above-mentioned functionality; similarly, sampler component 240 may correspond to sampler component 140 and sampler trigger 141 depicted in FIG. 1 and described above.

Amplifier component 230 comprises a high speed amplifier 231 receiving control signal input from an output attenuator control circuit 232 and an input gain control circuit 234; additionally, a digital to analog converter (DAC) component 233 may be provided. In operation, DAC component 233 may be operative to convert digital control signals 150B from a microprocessor or central processing unit (CPU), incorporated in processing unit 150 in FIG. 1, into appropriate voltage control signals 233A, 233B to affect operation of attenuator control circuit 232 and gain control circuit 234, respectively.

As is generally known in the art, attenuator circuits may be implemented on either the input side or the output side of an amplifier, or both; similarly, gain control may be implemented at either or both sides of an amplifier, or at various stages in an Op-Amp arrangement. Accordingly, those of skill in that art will appreciate that attenuator control circuit 232 may be implemented on the input side of high speed amplifier 231 and that gain control circuit 234 may be implemented on the output side of high speed amplifier 231. The FIG. 2 embodiment is provided by way of example only, and is not intended to be interpreted in any limiting sense with respect to the location of control circuits 232,234 relative to high speed amplifier 231.

As indicated in FIG. 2, control circuits 232 and 234 may separately include positive-intrinsic-negative (PIN) diodes. As is generally known in the art, a PIN diode is a current controlled circuit element; a forward biased PIN diode may behave as a current controlled resistor having desirable performance characteristics in low distortion attenuator and amplitude modulator applications. For example, when the control current to a forward biased PIN diode is varied continuously, the diode output may be used to level, attenuate, or to modulate radio frequency (RF) signal amplitudes. Accordingly, attenuator control circuit 232 and gain control circuit 234 may transmit control signals 232A and 234A, respectively, operative to adjust attenuation and gain of high speed amplifier 231 in accordance with signal 150B from processor unit 150.

High speed amplifier 231 may be operative to receive input signals 120C as shown in FIG. 2. Input signals 120C may be derived from signals or reflection pulses 199A, 198A received at line transformers 120 and transmitted from the duplexer as described above with reference to FIG. 1. In some embodiments, high speed amplifier 231 may be configured to accommodate input signals 120C in the 0.01 MHz-500 MHz frequency range. In addition to its variable gain functionality, high speed amplifier 231 may include circuitry operative to attenuate noise responsive to attenuation control signal 232A, as is generally known in the art.

Accordingly, wideband variable gain amplifier component 230 may enable all the functionality of a conventional variable gain amplifier while providing much wider bandwidth; the responsive frequency range of 0.01 MHz-500 MHz represents an improvement over existing variable gain amplifiers by as great as a factor of 500. Additionally, simple control circuits 232,234 comprising PIN diodes may enable variable gain amplifier component 230 to be responsive to a voltage input range of as great as 8 volts.

Output signals 130A from high speed amplifier 231, generally corresponding to signals designated by reference numeral 130A in FIG. 1, may be input to sampler component 240 as depicted in FIG. 2. Sampler component 240 comprises a wideband high speed sampler with an integrated A/D converter (sampler) 241, TDR sampler and spectrum analyzer acquisition control logic (logic) 242, and a data storage medium (memory) 243. In this embodiment, sampler component 240 may represent the hardware elements and functionality of both sampler component 140 as well as sampler trigger 141 depicted in FIG. 1.

Logic 242 generally comprises TDR sampler timebase logic as well as spectrum analyzer acquisition control logic as indicated in FIG. 2; accordingly, logic 242 may generally control the operational characteristics and functionality of sampler component 240 as set forth below. In that regard, logic 242 may receive control and timing signals represented by reference numerals 150D and 160A, respectively, in FIGS. 1 and 2; in this embodiment, signals 150D, 160A are received from processing unit 150 and asynchronous clock 160, respectively.

As indicated in FIG. 2, the TDR sampler portion and the spectrum analyzer portion of logic 242 may each include a complex programmable logic device (CPLD); it will be appreciated by those of skill in the art that logic 242 may additionally or alternatively incorporate a field-programmable gate array (FPGA), a programmable logic controller (PLC), or other programmable hardware or firmware elements. Accordingly, the functionality of logic 242 may be selectively altered in accordance with input control signal 150D, depending upon the desired operational characteristics of sampler component 240. Output from logic 242, i.e. signals 242A,242B, may generally be responsive to input signals 150D and 160A.

For example, the programmable circuitry resident in logic 242 may be configured to toggle sampler component 240 between one of two operating modes. In the FIG. 2 embodiment, for instance, logic 242 may selectively enable sampler component 240 to operate in a discrete acquisition TDR fault detection mode responsive to a particular level of input signal 150D, while enabling sampler component 240 to perform a continuous acquisition spectrum analyzer function at one or more selected frequencies responsive to a different level of input signal 150D. Depending upon the sophistication of logic 242 as well as the desired operability of sampler component 240 and the system in which it is utilized, logic 242 may be capable of selecting more than two operational modes, and may also be responsive to more input signals than indicated in FIG. 2.

In some embodiments, logic 242 may be designed and configured to be removable. Logic 242 implemented in a removable chip, board, or module may be removed and reprogrammed, for example, or replaced by a different hardware element having different or improved functionality. In the foregoing manner, the operability of sampler component 240 may be selectively altered or modified without requiring replacement of the entire hardware arrangement.

Output signals 242A,242B from logic 242 are generally a function of control and timing signals 150D, 160A; accordingly, the mode of operation, sample rate, and other functional characteristics of sampler 241 may be controlled by signal 242A, and utilization of memory 243 may be influenced by signal 242B.

As noted above with reference to FIG. 1, memory 243 may be implemented in various forms of storage media, including SRAM, for example, constructed and operative to store digital data. Referring back to FIG. 1, it will be appreciated that a CPU at processing unit 150 may operate at a substantially slower clock speed (e.g. 5.529 MHz) than the sample rate of sampler 241 as established by timing signal 160A. In some embodiments where the sampling rate of sampler 241 is greater than the CPU clock speed at processing unit 150, for example, memory 243 may buffer sample data for subsequent retrieval and analysis by processing unit 150.

In that regard, memory 243 may employ signal line 243A to receive sample data from sampler 241 and to transmit sample data to processing unit 150. As illustrated in FIG. 2, memory 243 may be provided with a 32K capacity, i.e. a capability of storing thirty-two thousand samples, each comprising 8 bits of data. Additionally or alternatively, memory 243 may be embodied in removable or replaceable chips such as single in-line memory modules (SIMMs) or dual in-line memory modules (DIMMs), for example, such that the capacity of memory 243 may be selectively modified. Similarly, sampler component 240 may comprise expansion slots or interfaces (not shown) to accommodate one or more additional memory chips; accordingly, capacity of memory 243 may be selectively altered depending, for instance, upon the application or desired functionality of the data acquisition system.

Responsive to an appropriate control input signal 150D, logic 242 may configure sampler 241 to operate as a spectrum analyzer under control of the spectrum analyzer CPLD. In a spectrum analyzer mode, sampler 241 may perform continuous, ie. streaming, sampling and A/D conversion of input signal 130A at one or more selected frequencies; in some embodiments, for example, sampler 241 may perform sampling of input signal 130A at 40 MHz. A 40 MHz sample frequency may be adequate for many practical situations; in accordance with the Nyquist Theorem of digital sampling, a 40 MHz sampling frequency is adequate to digitize an analog waveform having a frequency of about 20 MHz. By way of a practical example, current digital subscriber line (DSL) transmission lines typically operate at frequencies up to 8 MHz, while proposed standards such as very high data rate DSL (VDSL), for example, may increase the spectra beyond 10 MHz. It will be appreciated that the FIG. 2 embodiment may be readily adapted to sample at various frequencies.

Sampler 241 may incorporate high speed A/D converter circuitry configured and operative to accommodate the bandwidth and sample frequencies of the high speed sampler during ordinary operation.

In some situations mentioned briefly above, sampler 241 may execute sampling at a particular frequency, convert the samples to digital data, and transmit the sample data to memory 243, which may perform the role of a data buffer under certain circumstances. Sample data may be stored until memory 243 has reached capacity, at which point the entire contents of memory 243 may be transmitted to a CPU (e.g. at processing unit 150 in FIG. 1) in a single transmission; alternatively, data samples may be transmitted in blocks of a selected size (128 bits, 256 bits, etc.) depending, for example, upon the capabilities of the CPU and any data buffers associated therewith. In some instances where memory 243 is embodied in high capacity removable media such as flash memory cards, magnetic discs, compact discs (CDs), or digital versatile discs (DVDs), for example, memory 243 may be removed from sampler component 240 and inserted into an appropriate reader or disc drive unit for data retrieval.

For analysis of the full spectral content of signals propagating through transmission lines, fine resolution may require as much as the full 32k×8 bit data samples stored in the FIG. 2 embodiment of memory 243; conversely, as few as 512×8 bit samples may suffice for course resolution, for example, simply to resolve one frequency from another.

As is generally known in the art of spectrum analysis, the FIG. 2 arrangement may provide sufficient data for Fast Fourier Transform (FFT) analyses of spectral data related to operation of the transmission lines under test. Accordingly, amplitude of line transmission signals may be plotted as a function of frequency, facilitating analysis of the performance of the transmission line relative to expectations. Where no signal is propagating through the transmission line, the FIG. 2 embodiment operating in spectrum analysis mode may examine the transmission line for noise or interference.

In addition to streaming conversion of input signal 130A, sampler 241 may be configured to halt, or to “freeze,” its output. In this embodiment, control signal 150D may instruct logic 242 to freeze the timing component of signal 242A at the logic zero level. With its clock signal frozen, sampler 241 may hold the A/D converter circuitry in a frozen mode or condition, such that the most recent sample acquired by sampler 241 may be presented at the output of the A/D converter.

Responsive to an appropriate control input signal 150D, logic 242 may configure sampler 241 to operate in a discrete sampling TDR mode under control of the sampler timebase CPLD. In contrast to conventional TDR technology, however, wideband high speed sampler 241 may be configured to acquire more than a single data sample for each incident pulse transmitted through the transmission lines. Accordingly, sampler 241 may operate at a sufficient rate to obtain data on multiple events, for example, located at different locations in the transmission line; as a single incident pulse is transmitted through the line, multiple reflection pulses caused by various impedance discontinuities may be received and processed through wideband high speed data acquisition circuitry. Employing a wideband topology through amplifier component 230 and sampler component 240 may enable the FIG. 2 embodiment to sample multiple data points for a single incident pulse depending upon, for example, the frequency and duration of the incident pulse, the magnitude and duration of the reflection pulses, the sample rate as specified by the control signal 242A, and the like.

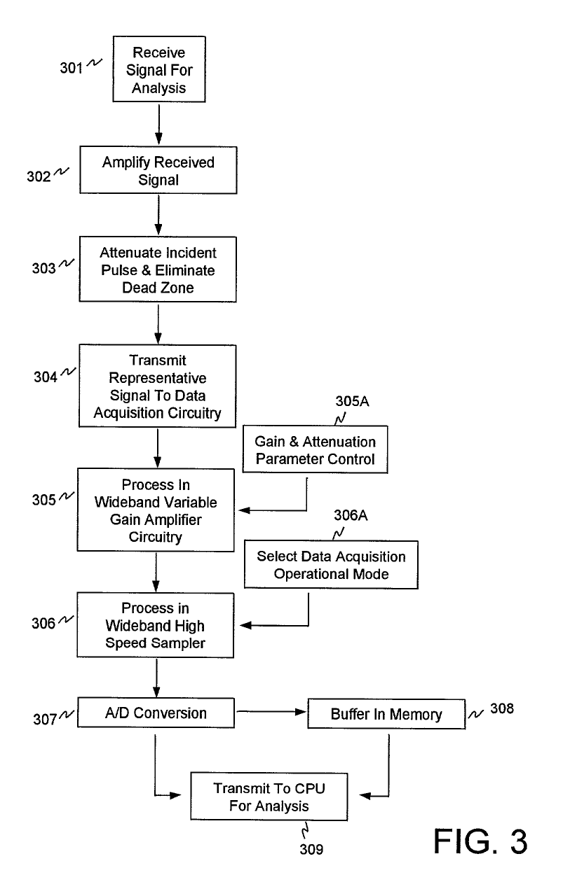

FIG. 3 is a simplified block diagram illustrating one embodiment of a data acquisition method. A signal to be analyzed may be received from a transmission line to be tested as indicated at block 301. As set forth above, when a multi-function data acquisition system is operating in a TDR mode, for example, the received signal may be a reflection pulse caused by an event in a transmission line; alternatively, when data acquisition is related to spectrum analysis and performance evaluation of the transmission line, the received signal may be a reflection pulse, an original incidence pulse, or other transmitted signal.

As described above with reference to FIG. 1, receiving a signal from a transmission line may be facilitated by wideband coupling circuitry capable of operating in the 10 kHz-500 MHz frequency range. A dual balanced duplexer may provide amplification (by a factor of 2 or more (2×) for example) for received signals as indicated at block 302. In some embodiments, the duplexer or equivalent circuitry may attenuate incident pulses and their effects (block 303) prior to transmitting the received signals to data acquisition circuitry; such attenuation of incident pulses upon reception may minimize or eliminate the “dead zone” characteristic of conventional TDR equipment.

A signal representative of the received signal (e.g. processed for amplification and attenuation of incident pulses as described above) may be transmitted to data acquisition circuitry at block 304. Initially, data acquisition may include forwarding this representative signal to wideband variable gain amplifier circuitry incorporating a high speed amplifier as indicated at block 305 for processing; gain and attenuation of the high speed amplifier may be selectively adjusted (block 305A), for example, from a remote terminal or other electronic system coupled to the data acquisition circuitry. Levels of gain and attenuation control parameters selected at block 305A may depend upon the configuration and desired operability of the system as a whole, and may generally be attained and maintained by control signal circuitry comprising PIN diodes as described in detail above with reference to FIG. 2.

Signals amplified and attenuated as described above may be forwarded to a wideband high speed sampler at block 306. As set forth in detail above, the mode of operation of sampler and the frequency at which it operates may be selectively controlled (block 306A) by logic responsive to a remote CPU and system clock signals. Sampler modes may include, among others, TDR and spectrum analyzer functionality.

Analog output from the sampler may be converted to digital signals by high speed A/C converter circuitry as represented at block 307. Digital sample data may be stored or temporarily buffered in a data storage medium or memory (block 308) as described above. Additionally or alternatively, digital sample data may be transmitted directly to a CPU or processing unit for analysis as indicated at block 309.

It will be appreciated that various alternatives exist with respect to the FIG. 3 embodiment, and that the presented order of the individual blocks is not intended to imply a specific sequence of operations to the exclusion of other possibilities; the particular application and overall system requirements may dictate the most efficient or desirable sequence of the operations set forth in FIG. 3. For example, the control parameter selections represented at blocks 305A and 306A may precede block 304, or occur prior to reception of signals for analysis at block 301. Similarly, transmission of sample data at block 309 may precede or supercede storing sample data in memory at block 308 in certain situations; where high capacity removable storage media is used as memory, stored data may not be transmitted as indicated at block 309, but rather the storage media itself may be inserted into an appropriate reader for data analysis as described above.

As noted above, the present system and method may enable simple control of attenuation and gain parameters in data acquisition circuitry for TDR and line performance or spectrum analysis applications. Additionally, enabling a TDR selectively to acquire multiple data samples per transmitted incident pulse may enable an integrated spectrum analyzer functionality as set forth in detail above.

The present invention has been illustrated and described in detail with reference to particular embodiments by way of example only, and not by way of limitation. Those of skill in the art will appreciate that various modifications to the disclosed embodiments are within the scope and contemplation of the invention. Therefore, it is intended that the invention be considered as limited only by the scope of the appended claims.

What is claimed is:

1. A method of acquiring data; said method comprising:
receiving an input signal to be analyzed from a transmission line;
amplifying a signal representative of said input signal using wideband variable gain amplifier circuitry; and
selectively sampling results of said amplifying using wideband high speed sampler circuitry in accordance with a selected sampling mode.

2. The method of claim 1 further comprising converting results of said selectively sampling to digital signals using high speed analog to digital converter circuitry.

3. The method of claim 1 further comprising storing results of said selectively sampling in a digital data storage medium.

4. The method of claim 3 further comprising transmitting results of said selectively sampling to a processing unit for analysis.

5. The method of claim 1 wherein said receiving comprises utilizing wideband coupling circuitry operable to receive said input signal from said transmission line in the 10 kHz-500 MHz frequency range.

6. The method of claim 1 wherein said amplifying comprises selectively utilizing gain control circuitry comprising a positive-intrinsic-negative diode.

7. The method of claim 1 further comprising attenuating results of said amplifying using attenuator control circuitry comprising a positive-intrinsic-negative diode.

8. The method of claim 1 wherein said selectively sampling comprises acquiring a single data sample per incident pulse transmitted through said transmission line.

9. The method of claim 1 wherein said selectively sampling comprises acquiring a plurality of data samples per incident pulse transmitted through said transmission line.

10. A data acquisition apparatus comprising:
wideband coupling circuitry operable to receive an input signal in the 10 kHz-500 MHz frequency range from a transmission line;
wideband variable gain amplifier circuitry incorporating a high speed amplifier and operative to amplify a signal representative of said input signal;
wideband high speed sampler circuitry operative to sample output from said high speed amplifier; and
a processing unit coupled to said amplifier circuitry and to said sampler circuitry and operative to select an operating mode for said sampler circuitry.

11. The apparatus of claim 10 wherein said wideband coupling circuitry comprises a duplexer.

12. The apparatus of claim 10 wherein said amplifier circuitry comprises a gain control circuit and an attenuator control circuit and wherein said gain control circuit and said attenuator control circuit are responsive to signals transmitted from said processing unit.

13. The apparatus of claim 10 wherein said sampler circuitry comprises a high speed analog to digital converter.

14. The apparatus of claim 10 wherein said sampler circuitry comprises a complex programmable logic device operative to configure said operating mode of said sampler circuitry responsive to signals from said processing unit.

15. The apparatus of claim 14 wherein said logic device is selectively operative to configure said sampler circuitry to function as a spectrum analyzer.

16. The apparatus of claim 14 wherein said logic device is selectively operative to configure said sampler circuitry to function as a time domain reflectometer.

17. The apparatus of claim 16 wherein said sampler circuitry is configured in a single sample mode to acquire a single data sample per incident pulse transmitted through said transmission line.

18. The apparatus of claim 16 wherein said sampler circuitry is configured in a streaming data acquisition mode to acquire a plurality of data samples per incident pulse transmitted through said transmission line.

19. The apparatus of claim 10 further comprising a sample data storage medium selectively operative to store output from said sampler circuitry.

20. The apparatus of claim 10 further comprising a bi-directional data coupling component enabling two way data communication between said processing unit and a remote device.

21. The apparatus of claim 20 wherein said operating mode for said sampler circuitry is selected by said processing unit responsive to instructions from said remote device.

22. A multi-function data acquisition system comprising:
means for receiving an input signal to be analyzed from a transmission line;
a wideband variable gain amplifier coupled to said means for receiving and operative to amplify a signal representative of said input signal;
a wideband high speed sampler operative in accordance with a plurality of sampling modes; and
a processing unit operative to cause said sampler selectively to function in accordance with one of said plurality of sampling modes.

23. The system of claim 22 further comprising a high speed analog to digital converter operative to convert output from said sampler to digital signals.

24. The system of claim 22 further comprising a digital data storage medium receiving and storing sample data output from said sampler.

25. The system of claim 22 wherein said processing unit is operative to perform data analysis on output from said sampler.

26. The system of claim 22 wherein said means for receiving comprises wideband coupling circuitry operable to receive said input signal from said transmission line in the 10 kHz-500 MHz frequency range.

27. The system of claim 22 wherein said amplifier further comprises gain control circuitry including a positive-intrinsic-negative diode responsive to signals from said processing unit.

28. The system of claim 22 wherein said amplifier further comprises an attenuator control circuit including a positive-intrinsic-negative diode responsive to signals from said processing unit.

29. The system of claim 22 wherein said processing unit is operatively coupled to a remote device.

30. The system of claim 22 wherein said processing unit is selectively operative to configure said sampler to function in a spectrum analyzer mode.

31. The system of claim 22 wherein said processing unit is selectively operative to configure said sampler to function in a time domain reflectometer mode.

32. The system of claim 31 wherein said sampler is configured to acquire a single data sample per incident pulse transmitted through said transmission line.

33. The system of claim 31 wherein said sampler is configured to acquire a plurality of data samples per incident pulse transmitted through said transmission line.
